(19) United States
(12) Patent Application Publication
(10) Pub. No.: US 2024/0224654 A1
(43) Pub. Date: Jul. 4, 2024

(54) DISPLAY APPARATUS

(71) Applicant: LG Display Co., Ltd., Seoul (KR)

(72) Inventors: Jaeyoung OH, Goyang-si (KR); Youngju KOH, Paju-si (KR)

(73) Assignee: LG Display Co., Ltd., Seoul (KR)

(21) Appl. No.: 18/398,503

(22) Filed: Dec. 28, 2023

(30) Foreign Application Priority Data
Dec. 30, 2022 (KR) 10-2022-0191257

(51) Int. Cl. H10K 59/131; H10K 59/122

(52) U.S. Cl. CPC H10K 59/131; H10K 59/122

(57) ABSTRACT

A display apparatus includes a plurality of sub pixels, gate lines and data lines being disposed on a substrate; a bank being disposed on the substrate, being provided with a bank hole that comprises a first opening area and a second opening area which is elongated from the first opening area toward the gate line, and distinguishing a light-emitting area of each of the sub pixels; and a plurality of connection wire lines being disposed to overlap with the light-emitting area of the sub pixel, wherein the gate line is disposed along a shape of at least one of corner portions of the second opening area.

### CROSS-REFERENCE TO RELATED APPLICATION

This application claims the priority of Korean Patent Application No. 10-2022-0191257 filed on Dec. 30, 2022, which is hereby incorporated by reference in its entirety.

### BACKGROUND

### Field of the Disclosure

The present disclosure relates to a display apparatus, and more particularly, for example, without limitation, to a display apparatus that ensures improvement in an opening ratio and electrical properties of elements.

### Description of the Background

Display apparatuses are applied to a variety of electronic devices such as a TV, a mobile phone, a laptop, a table, a monitor, a wearable apparatus, an electronic book, a portable multimedia player (PMP), a navigation apparatus, a wall paper display apparatus, a signage apparatus, a game machine, a camera and the like. Under the circumstances, research into development of a display apparatus that is thin, is lightweight and consumes less power.

Display apparatuses may comprise liquid crystal display (LCD) devices, plasma display panel (PDP) devices, quantum dot light-emitting display devices, micro light-emitting diode display devices, electrophoresis display devices, and organic light-emitting display (OLED) devices and the like.

Among the display apparatuses, an organic light-emitting display (OLED) device comprises a plurality of pixel areas being arranged in a display area that displays an image, and a plurality of organic emission elements that corresponds to the plurality of pixel areas. An organic emission element emits light on its own. Accordingly, an organic light-emitting display device responds more rapidly, has a higher luminous efficiency, luminance and viewing angle, and is more excellent in a contrast ratio and a color gamut than a liquid crystal display device.

The organic light-emitting display device comprises a light-emitting part, and a circuit part for driving the light-emitting part. The circuit part comprises a thin film transistor and a storage capacitor and the like. In manufacturing of a display apparatus comprising an organic emission element, it is important to perform research into a method of ensuring an opening ratio to embody a high-resolution screen.

The description provided in the background section should not be assumed to be prior art merely because it is mentioned in or associated with that section. The discussion of the background section may include information that describes one or more aspects of the subject technology, and the description in this section does not limit the invention.

### SUMMARY

Accordingly, the present disclosure is directed to a display apparatus that substantially achieves the desires described above.

More specifically, the present disclosure is to provide a display apparatus that may ensure an opening ratio for embodying a high-resolution screen.

The present disclosure is also to provide a display apparatus in which the space of a sub pixel area may be used efficiently to increase an opening ratio, ensuring improvement in the lifespan of an organic emission element.

Further, the present disclosure is to provide a display apparatus that may prevent degradation of electrical properties of an element while increasing the surface area of a light-emitting area.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

The present disclosure is not limited to the above ones, and other aspects and advantages that are not mentioned above may be clearly understood from the following description and may be more clearly understood from the aspects set forth herein. Additionally, the aspects and advantages in the present disclosure may be realized via means and combinations thereof that are described in the appended claim.

To achieve these and other advantages and in accordance with the present disclosure, as embodied and broadly described, a display apparatus includes a plurality of sub pixels, gate lines and data lines being disposed on a substrate; a bank being disposed on the substrate, being provided with a bank hole that comprises a first opening area and a second opening area which is elongated from the first opening area toward the gate line, and distinguishing a light-emitting area of each of the sub pixels; and a plurality of connection wire lines being disposed to overlap with the light-emitting area of the sub pixel, wherein the gate line is disposed along a shape of at least one of corner portions of the second opening area.

In another aspect of the present disclosure, a display apparatus includes a substrate comprising sub pixels; a gate line being disposed on the substrate along a first direction; a data line being disposed along a second direction across the first direction; a bank comprising a bank hole that distinguishes a light-emitting area of each of the sub pixels and comprises at least one or more of corner portions, wherein the gate line comprises a first bend portion being spaced from one side of the bank hole by a first distance, and a second bend portion being disposed along the corner portion of the bank hole and being spaced from the corner portion of the bank hole by a second distance less than the first distance.

In one aspect of the present disclosure, since a connection wire line connecting components electrically comprises a transparent semiconductor material, the surface area of a light-emitting area may increase. Accordingly, the space of a sub pixel may be used efficiently to increase an opening ratio, thereby embodying a high-resolution screen.

Additionally, since the surface area of the light-emitting area increases, power consumption for realizing the same luminance in each sub pixel may decrease, thereby ensuring improvement in the lifespan of a display apparatus.

Further, a distance between a light-emitting area and a transistor may be ensured while the surface area of the light-emitting area increases, the input of light to an active layer of the transistor may be suppressed. Thus, the degradation of the properties where a threshold voltage moves to a minus may be reduced or prevented, thereby ensuring the stability and reliability of elements.

Further, a gate line may be disposed to surround at least one of edge portions of an opening area, to ensure a distance between a sensing transistor or a switching transistor and the opening area, thereby reducing or preventing the input of light to the active layer. Thus, the lifespan of an organic emission element may increase, thereby making it possible to drive the display apparatus even with lower power and reduce power consumption.

Furthermore, since a color filter is not disposed at a white sub pixel, light is directly input to the white sub pixel, and the white sub pixel is sensitive to white light. In the aspect of the present disclosure, the gate line may be sufficiently spaced from a bank hole through which light is emitted by a structure surrounding both sides of the corner portion of an opening area. Accordingly, the input of light to the transistor may be suppressed, and the problem that threshold voltage properties are degraded may be solved, thereby ensuring the reliability of elements and making it possible to operate the display apparatus with low power and reduce power consumption.

Aspects according to the present disclosure are not limited to the above ones, and other aspects that are not mentioned above may be clearly understood from the following description by one having ordinary skill in the art.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a view showing a display apparatus of one aspect of the present disclosure;

FIGS. 2 and 3 are plan views showing part of a sub pixel area disposed on a display area in FIG. 1 of one exemplary embodiment;

FIG. 4 is a cross-sectional view showing portion I-I′ cut away from FIG. 2 of one exemplary embodiment;

FIG. 5 is a cross-sectional view showing portion II-II′ cut away from FIG. 2 of one exemplary embodiment;

FIGS. 6 and 7 are cross-sectional views for explaining a problem or limitation caused by an input of light into an active layer; and

FIGS. 8 and 9 are graphs showing properties based on a distance between a transistor and an opening area of a light-emitting area of one exemplary embodiment.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

Advantages and features in the present disclosure and a method of ensuring the same may be clearly understood from aspects that are described hereafter with reference to accompanying drawings. Aspects of the disclosure, however, may be embodied in various different forms, and should not be construed as being limited to the aspects set forth herein. Rather, the aspects set forth herein are provided as examples so that the disclosure may be thorough and complete and may fully convey the scope of the disclosure to one having ordinary skill in the art.

Throughout the drawings and the detailed description, unless otherwise described, the same drawing reference numerals should be understood to refer to the same elements, features, and structures. The relative size and depiction of these elements may be exaggerated for clarity, illustration, and convenience. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

The shapes, sizes, ratios, angles, number and the like of the components illustrated in the drawings provided for describing the aspects of the disclosure are given only as examples, and the subject matter of the disclosure is not limited by the particulars in the drawings. Throughout the disclosure, like reference numerals denote like components. In description of the subject matter of the disclosure, detailed description of well-known technologies relevant to the subject matter of the disclosure is omitted or may be briefly provided if it is deemed to make the gist of the disclosure unnecessarily vague.

Throughout the disclosure, terms such as “comprise,” “have,” “being comprised of” and the like are to imply the inclusion of any other component, but for a term such as “only.” Further, the singular forms “a,” “an” and “the” are intended to include the plural forms as well, unless explicitly stated otherwise.

Any implementation described herein as an “example” is not necessarily to be construed as preferred or advantageous over other implementations.

In describing a component, the margin of error is to be included, though not explicitly described.

In the disclosure, when spatial terms such as “being on,” “being in an upper portion,” “being in a lower portion,” “being adjacent to” and the like are used to describe a position relationship between two components, one or more additional components may be interposed between the two components unless terms such as “right” or “directly” are used.

When temporal terms such as “after,” “next,” “following,” “before” and the like are used to describe a temporal order, one or more additional events may be interposed between two events unless a term such as “right” or “directly” is used.

In describing components, terms such as first, second and the like may be used. These terms are only intended to distinguish one component from another component, and the components are not limited by the terms. Accordingly, a first component described hereafter may be a second component within the technical spirit of the disclosure.

Features of the aspects of the disclosure may be partially or entirely mixed or combined, and may technically link and operate in various ways. Further, each aspect may be embodied independently, or in connection with each other.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first item, a second item, and a third item” encompasses the combination of all three listed elements, combinations of any two of the three elements, as well as each individual element, the first element, the second element, and the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereafter, a display apparatus in each aspect is described with reference to the accompanying drawings. Further, all the components of each ultrasonic sensor and each display apparatus having the ultrasonic sensor according to all embodiments of the present disclosure are operatively coupled and configured. For convenience of description, a scale of each of elements illustrated in the accompanying drawings differs from a real scale, and thus, is not limited to a scale illustrated in the drawings.

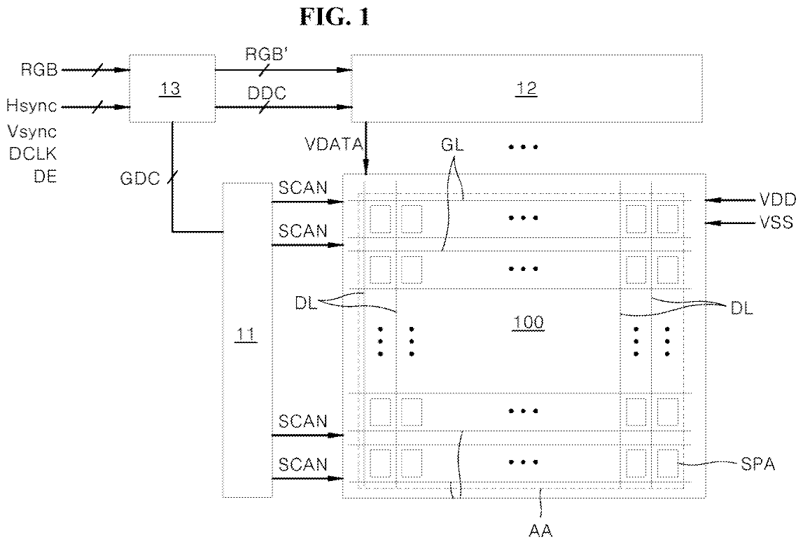

FIG. 1 is a view showing a display apparatus of one aspect. Referring to FIG. 1, the display apparatus may comprises a display panel 100 comprising a display area AA, and a panel driver 11, 12, 13 for providing a driving signal to the display panel 100. The display panel 100 may comprises a display area AA that outputs an image, and a plurality of sub pixels (sub pixel areas; SPA) that is disposed sides by side on the display area AA and respectively outputs light for displaying an image.

Each of the plurality of sub pixels SPA may emits light in a wavelength zone corresponding to any one of multiple different colors. The multiple colors may comprise red, green and blue but not be limited. For example, the sub pixels may comprise a red sub pixel, a green sub pixel, a blue sub pixel, and a white sub pixel. As an example, the multiple colors may further or alternatively comprise magenta, cyan and yellow, without being limited thereto.

The display panel 100 may further comprises signal lines GL, DL connecting to the plurality of sub pixels SPA. The signal lines GL, DL may transfer a driving signal of the panel driver 11, 12, 13 to each sub pixel SPA. In an example, the display panel 100 may comprise a gate line GL for providing a scan signal SCAN, and a data line DL for providing a data signal.

The display panel 100 may further comprise first and/or second driving power lines that transfer first and/or second driving power sources VDD, VSS for driving an emission element disposed at each sub pixel SPA.

The panel driver 11, 12, 13 of the display apparatus may comprise a gate driver 11 connecting to the gate line GL of the display panel 100, a data driver 12 connecting to the data line DL of the display panel 100, and a timing controller 13 controlling the driving timing of each of the gate driver 11 and the data driver 12, without being limited thereto. As an example, at least one of the above-mentioned components could be omitted, and/or an additional component may be further included.

The timing controller 13 may rearrange digital video date RGB input from the outside, e.g. a host system, to correspond to the resolution of the display panel 100, and provide the rearranged digital video data RGB′ to the data driver 12. The host system may be any one of various electronic devices such as a television system, a set-top box, a navigation system, a DVD player, a Blu-ray player, a personal computer (PC), a home theater system, a phone system, and the like.

The timing controller 13 provides a data control signal DDC for controlling the operation timing of the data driver 12, and a gate control signal GDC for controlling the operation timing of the gate driver 11, based on timing signals such as a vertical synchronization signal Vsync, a horizontal synchronization signal Hsync, a dot clock signal DCLK, and a data enable signal DE and the like. The timing signals may be synchronized with the digital video date RGB.

The gate driver 11 provides a scan signal SCAN to a plurality of gate lines GL. As an example, the gate driver 11 provides a scan signal SCAN consecutively to a plurality of gate lines GL in one frame duration for displaying an image, based on the gate control signal GDC, without being limited thereto. The gate line GL may correspond to sub pixels SPA horizontally disposed side by side, among the plurality of sub pixels SPA, without being limited thereto.

The data driver 12 converts rearranged digital video data RGB′ into analog data voltages, based on a data control signal DDC. The data driver 12 provides a data signal VDATA corresponding to each sub pixel SPA that corresponds to each gate line GL for each horizontal duration, based on the rearranged digital video data RGB′, to the data line DL. Although it is illustrated in FIG. 1 that the timing controller 13, the gate driver 11 and the data driver 12 are disposed separately from the display panel 100, embodiments are not limited thereto. As an example, at least one of the timing controller 13, the gate driver 11 and the data driver 12 could be disposed on the display panel, for example, in a Gate in Panel (GIP) method, without being limited thereto.

Each of the plurality of gate lines GL may extend in a first direction of the display panel 100, and each of the plurality of data lines DL may extend in a second direction across the first direction of the display panel 100. The gate line GL and the data line DL are disposed in a way that the gate line GL and the data line DL cross, and define a sub pixel SPA.

The plurality of sub pixels SPA disposed on the display area AA may be arranged in a matrix form ((M*N, M and N are natural numbers), along a horizontal direction and a perpendicular direction. Each sub pixel SPA may electrically connect to one of the plurality of gate lines GL, and one of the plurality of data lines DL.

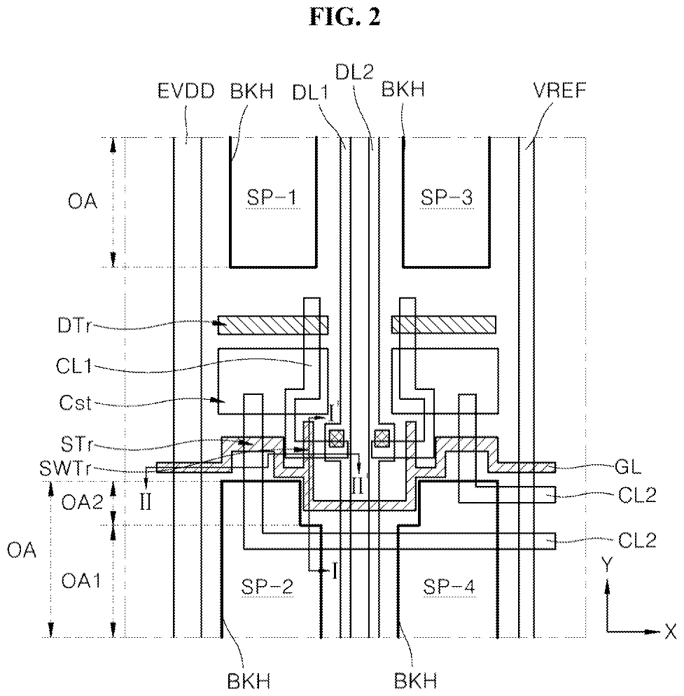

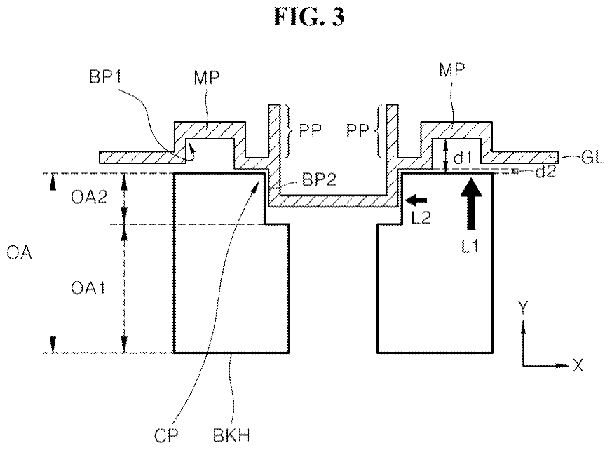

FIGS. 2 and 3 are plan views showing part of a sub pixel area disposed on a display area in FIG. 1. FIG. 2 shows four sub pixel SPA that are adjacent to each other, among the plurality of sub pixels SPA. FIG. 3 schematically shows a gate line portion and a bank hole portion for convenience of description of the aspect.

Referring to FIGS. 1 to 3, a plurality of sub pixels SPA may be disposed on a display area AA. A sub pixel SPA comprises a first sub pixel SP-1, a second sub pixel SP-2, a third sub pixel SP-3, and a fourth sub pixel SP-4 that are arranged in a way that the first sub pixel SP-1, the second sub pixel SP-2, the third sub pixel SP-3, and the fourth sub pixel SP-4 are adjacent to each other in upward, downward, leftward and rearward directions. For example, the first sub pixel SP-1 may comprise a green sub pixel, the second sub pixel SP-2 may comprise a red sub pixel, the third sub pixel SP-3 may comprise a blue sub pixel, and the fourth sub pixel SP-4 may comprise a white sub pixel, without being limited thereto. In the aspect, four sub pixels are described for convenience of description, but not being limited. As an example, the first sub pixel SP-1, the second sub pixel SP-2, the third sub pixel SP-3, and the fourth sub pixel SP-4 may emit light of the same color, or at least one of the first sub pixel SP-1, the second sub pixel SP-2, the third sub pixel SP-3, and the fourth sub pixel SP-4 may emit light of a color different from that of the remaining ones.

In one aspect, the first sub pixel SP-1 and the third sub pixel SP-3 are spaced from each other in the X-axis direction that is the first direction, and the second sub pixel SP-2 and the fourth sub pixel SP-4 are spaced from each other in the X-axis direction that is the first direction. Additionally, the first sub pixel SP-1 and the second sub pixel SP-2 are spaced from each other in the Y-axis direction that is the second direction perpendicularly across the first direction, and the third sub pixel SP-3 and the fourth sub pixel SP-4 are spaced from each other in the Y-axis direction that is the second direction. The X-axis direction may also be referred to as a horizontal line, and the Y-axis direction may also be referred to as a perpendicular line. Embodiments are not limited thereto. As an example, the second direction may obliquely across the first direction.

Each of the sub pixels SP-1, SP-2, SP-3, SP-4 comprises a light-emitting area in which an organic emission layer emitting light is disposed, and a circuit part which is provided with circuit elements for providing driving current to the organic emission layer.

The light-emitting area may be defined by a bank hole BKH that is an opening area provided at a bank. The surface area of the light-emitting area may be understood as the surface area of the bank hole BKH. A light-emitting structure comprising a first electrode, an organic emission layer and a second electrode may be disposed on the light-emitting area comprising the bank hole BKH.

The bank hole BKH may comprise a first opening area OA1 and a second opening area OA2. The second opening area OA2 may have a polygonal shape (e.g., a rectangle shape) that is elongated from the first opening area OA1 and comprises at least one or more of corner portions (CP; see FIG. 3). The second opening area OA2 may be formed in a way that the second opening area OA2 protrudes in the Y-axis direction from the first opening area OA1. As an example, the width of the second opening area OA2 may be less than the width of the first opening area OA1, but not limited.

A circuit element may comprise a driving transistor DTr, a storage capacitor Cst, a sensing transistor STr, and a switching transistor SWTr. Circuit elements constituting a circuit part are disposed in the remaining area except for the light-emitting area. Embodiments are not limited thereto. As an example, at least one of the above-mentioned components (e.g., the sensing transistor STr) may be omitted, and/or an additional component may be further included.

In the aspect, circuit elements, which constitute a circuit part disposed between the first sub pixel SP-1 and the second sub pixel SP-2, are described. Circuit elements, which constitute a circuit part disposed between the third sub pixel SP-3 and the fourth sub pixel SP-4, may have the same or similar configuration as or the different configuration from the configurations the circuit elements of the first sub pixel SP-1 and the second sub pixel SP-2.

A driving power supply line EVDD is disposed at one side of the first sub pixel SP-1 and the second sub pixel SP-2. The driving power supply line EVDD may extend and be disposed along the Y-axis direction that is the second direction. The driving power supply line EVDD may provide a power source voltage.

A data line DL1, DL2 is disposed between the first sub pixel SP-1 and the third sub pixel SP-3, and between the second sub pixel SP-2 and the fourth sub pixel SP-4. The data line DL1, DL2 provides data signals generated by the data driver 12 to the display area.

The data line DL1, DL2 may extend and be disposed along the Y-axis direction that is the second direction. The data line DL1, DL2 may comprise a first data line DL1 and a second data line DL2. The data line DL1, DL2 may comprise a first data line DL1 disposed at the other side of the first sub pixel SP-1 and at the other side of the second sub pixel SP-2, and a second data line DL2 disposed at one side of the third sub pixel SP-3 and at one side of the fourth sub pixel SP-4. The first data line DL1 and the second data line DL2 are spaced from each other. A reference power supply line VREF is disposed at the other side of the third sub pixel SP-3. The reference power supply line VREF may extend and be disposed along the Y-axis direction that is the second direction.

The gate line GL is disposed across the driving power supply line EVDD, the first data line DL1, the second data line DL2, and the reference power supply line VREF that are arranged in the X-axis direction. The gate line GL may extend and be disposed along the X-axis direction.

The gate line GL may provide a scan signal for selecting each horizontal line while a data signal is supplied to an individual sub pixel SP-1, SP-2, SP-3, SP-4 through the first and second data lines DL1, DL2.

The gate line GL extends from the first sub pixel SP-1 toward the third sub pixel SP-3. Referring to FIG. 3, the gate line GL may comprise a main pattern portion MP comprising at least one or more of bend portions BP1, BP2. The bend portions BP1, BP2 may comprise a first bend portion BP1 and a second bend portion BP2. The first bend portion BP1 is spaced by a first distance d1 apart from one side (e.g., an upper side) of the second opening area OA2 of the bank hole BKH. The second bend portion BP2 is disposed along the corner portion CP of the second opening area OA2 and spaced by a second distance d2 apart from the one side of the second opening area OA2. The first distance d1 may be greater than the second distance d2. Accordingly, the first bend portion BP1 may be farther from the second opening area OA2 of the bank hole BKH than the second bend portion BP2.

Additionally, the gate line GL may comprise a projection pattern portion PP that is branched from the main pattern portion MP extending from the first sub pixel SP-1 toward the second sub pixel SP-2, and protrudes in the Y-axis direction. The gate line GL may be disposed across each connection wire lines CL1, CL2. Part of the gate line GL may constitute a sensing transistor STr or a switching transistor SWTr. As an example, part of the gate line GL disposed across each connection wire lines CL1, CL2 may constitute the sensing transistor STr or the switching transistor SWTr.

The gate line GL may be disposed along the shape of at least one or more of corner portions CP of the second opening area OA2 that is a protruding portion of the bank hole BKH of the light-emitting area. For example, the gate line GL may be disposed to surround one corner portion CP of the second opening area OA. Accordingly, the gate line GL may be disposed along the side portion that connects from the corner portion CP of the second opening area OA2 of the bank hole BKH.

The driving transistor DTr switches a driving power source that is supplied to an organic emission element disposed to correspond to each of the sub pixels SP-1, SP-2, SP-3 and SP-4. In an example, a driving transistor DTr disposed at the first sub pixel SP-1 may connect to the driving power supply line EVDD electrically.

The storage capacitor Cst may be disposed between the driving transistor DTr and the gate line GL. The storage capacitor Cst serves to charge a voltage supplied through the driving power supply line EVDD, and to allow the organic emission element to keep emitting, for example, for one frame period.

The switching transistors SWTr may electrically connect through a first connection wire line CL1 that connects the driving transistor Dtr and the data line DL1. As the switching transistor SWTr is turned on, a data voltage supplied through the data line DL1 may be provided to the driving transistor Dtr.

The sensing transistor STr may connect to the reference voltage supply line VREF that provides a sensing signal through a second connection wire line CL2. In the aspect, the sensing transistor STr may be turned on by a scan signal that is provided from the gate line GL. As the sensing transistor is turned on, a sensing signal of the reference voltage supply line VREF may be provided to the storage capacitor Cst.

As the driving transistor DTr is turned on, a power source supplied from the driving power supply line EVDD may be supplied to the organic emission element, to emit light. Additionally, the storage capacitor Cst may keep a voltage of a gate electrode of the driving transistor DTr constant, to allow the organic emission element to keep emitting light, while the driving transistor DTr is turned on.

The gate electrode of the sensing transistor STr and the switching transistor SWTr may be a portion that is branched from part of the gate line GL or the gate line GL.

Referring back to FIGS. 2 and 3, the gate line GL is disposed from the first sub pixel SP-1 to the third sub pixel SP-3, and extends along the X-axis direction that is the first direction. The gate line GL may comprise a main pattern portion MP comprising at least one or more of bend portions BP1, BP2. The bend portion BP1, BP2 of the main pattern portion MP of the gate line GL may be disposed along the shape of at least one or more of corner portions CP of the second opening area OA2 of the bank hole BKH. For example, the gate line GL may be disposed to surround the corner portion of the second opening area OA2. Part of the main pattern part MP of the gate line GL may be disposed across the second connection wire line CL2, and provided as the sensing transistor STr.

Additionally, the gate line GL may comprise a projection pattern portion PP that is branched and protrudes in the Y-axis direction from the main pattern portion MP elongated along the first direction. The projection pattern portion PP may be disposed across the first connection wire line CL1 connecting the driving transistor Dtr and the data line DL1, and provided as the switching transistor SWTr.

Further, the gate line GL may be disposed to surround both corner portions of the second opening area OA2 close to the gate line GL while extending from the first sub pixel SP-1 toward the third sub pixel SP-3.

The connection wire line CL1, CL2 may comprise a first connection wire line CL1 and a second connection wire line CL2. The first connection wire line CL1 may connect the driving transistor DTr and the data line DL1, and electrically connect to the switching transistor SWTr. The second connection wire line CL2 may connect the sensing transistor STr and the reference voltage supply line VREF electrically.

As an example, the first and second connection wire lines CL1, CL2 may comprise a transparent semiconductor material. In an example, the first and second connection wire lines CL1, CL2 may comprise at least one of an indium-gallium-zinc-oxide (IGZO)-based semiconductor material, an indium-zinc-oxide (IZO)-based semiconductor material, and the like. As an example, at least one of the first and second connection wire lines CL1, CL2 may pass through the opening area OA, without being limited thereto. As an example, at least one of the first and second connection wire lines CL1, CL2 may bypass the opening area OA, without being limited thereto.

As an example, the first and second connection wire lines CL1, CL2 may comprise a semitransparent semiconductor material. In an example, the first and second connection wire lines CL1, CL2 may comprise indium tin oxide (ITO) or indium zinc oxide (IZO), but embodiments of the present disclosure are not limited thereto.

As an example, the first and second connection wire lines CL1, CL2 may comprise an opaque semiconductor material. In an example, the first and second connection wire lines CL1, CL2 may comprise at least one of aluminum (Al), copper (Cu), gold (Au), silver (Ag), molybdenum (Mo), Mg, or the like, but embodiments of the present disclosure are not limited thereto.

The projection pattern portion PP being branched and protruding in the Y-axis direction of the gate line GL is disposed to overlap (e.g., over or below) the first or second connection wire line CL1, CL2, across the first or second connection wire line CL1, CL2. Accordingly, a portion of the first or second connection wire line CL1, CL2, which overlaps with the gate line GL, may become a channel area, and be embodied as the switching transistor SWTr or the sensing transistor STr. Additionally, a portion of the first or second connection wire line CL1, CL2, which does not overlap with the gate line GL, may comprise a conductived semiconductor material.

As an example, since the first or second connection wire line CL1, CL2 is comprised of a transparent conductive semiconductor material, at least one of the first or second connection wire lines CL1, CL2 may extend in the direction toward the light-emitting area and be disposed to overlap with a portion of the surface area of one or more light-emitting areas. In an example, the second connection wire line CL2 may extend in the direction toward the light-emitting area of the fourth sub pixel SP-4 while overlapping with the light-emitting area of the second sub pixel SP-2, and be disposed to overlap with the light-emitting area of the fourth sub pixel SP-4.

In the case where the first or second connection wire line comprises an opaque conductive material (e.g., metallic material), an area where the first or second connection wire line is disposed distinguishes from the light-emitting area, to reduce or prevent the area from overlapping with the light-emitting area. Accordingly, the surface area of the light-emitting area, which may be ensured in each sub pixel having a limited space, is limited. In one aspect, since the first or second connection wire line CL1, CL2 comprises a transparent semiconductor material, the first or second connection wire line CL1, CL2 may be disposed to overlap with the light-emitting area. Thus, since the first and second connection wire lines CL1, CL2 are disposed on an additional space, the opening area OA of the bank hole BNK may expand by the second opening area OA2, thereby ensuring an increase in an opening ratio.

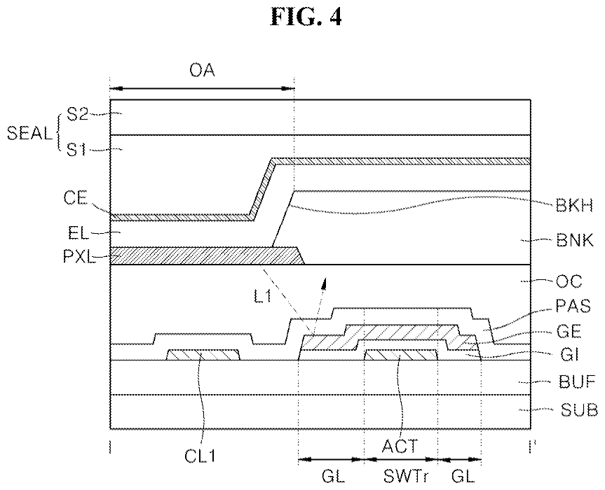

The driving transistor DTr and the sensing transistor STr may have the same or similar structure as the switching transistor SWTr. For example, the switching transistor SWTr, as illustrated in FIG. 4, may comprise an active layer ACT, a gate insulation layer GI, and a gate electrode GE.

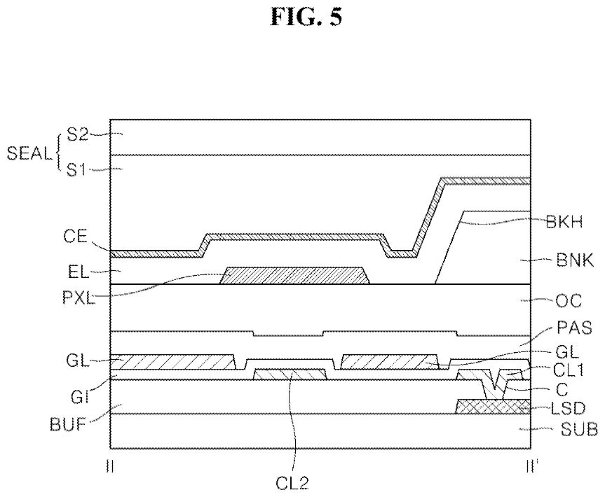

FIG. 4 is a cross-sectional view showing portion I-I′ cut away from FIG. 2 according to an exemplary embodiment of the present application. FIG. 5 is a cross-sectional view showing portion II-II′ cut away from FIG. 2 according to an exemplary embodiment of the present application.

Referring to FIGS. 4 and 5, a light shielding layer LSD may be disposed on a substrate SUB. The light shielding layer LSD may be disposed on the same planar surface as the driving power supply line EVDD, the reference power supply line VREF and/or the data line DL1, DL2, without being limited thereto. As an example, at least one of the driving power supply line EVDD, the reference power supply line VREF, the data line DL1, DL2, and the light shielding layer LSD may be disposed on a different layer. The light shielding layer LSD may comprise an opaque metallic material. For example, the light shielding layer LSD may comprise an opaque metallic material such as molybdenum (Mo), aluminum (Al), titanium (Ti), copper (Cu) and the like or an alloy thereof. As an example, the light shielding layer LSD may be omitted according to the design.

A buffer layer BUF may be disposed on the substrate SUB comprising the light shielding layer LSD. The buffer layer BUF may cover the surface of the substrate SUB entirely. The buffer layer BUF may comprise an insulation material, e.g., a silicon oxide or a silicon nitride and the like, without being limited thereto. Referring to FIG. 5, the buffer layer BUF may comprise a contact hole C that exposes a portion of the surface of the light shielding layer LSD constituting the first data line (DL1; see FIG. 2).

An active layer ACT is disposed on the buffer layer BUF. As an example, the active layer ACT may comprise a transparent semiconductor material. As an example, the active layer ACT may comprise at least one of an indium-gallium-zinc-oxide (IGZO)-based transparent semiconductor material, an indium-zinc-oxide (IZO)-based transparent semiconductor material, and the like. The active layer may be disposed as the first connection wire line CL1 while filling the contact hole C that exposes a portion of the surface of the light shielding layer LSD constituting the first data line (DL1; see FIG. 2).

The first and second connection wire lines CL1, CL2 may be formed with the same or similar material, on the same planar surface as the active layer ACT. In an example, the first and second connection wire lines CL1, CL2 may comprise a transparent conductive semiconductor material. Embodiments are not limited thereto. As an example, the first and second connection wire lines CL1, CL2 may be formed with the different materials, on the same or different planar surfaces.

A gate electrode GE may be disposed on the active layer ACT that is disposed in the area where the transistor is disposed. The gate electrode GE of at least one of the switching transistor and the sensing transistor may be a portion of the gate line GL. For example, the gate electrode GE of the switching transistor SWTr may be defined by a projection pattern portion (PP; see FIG. 3) that is branched and protrudes from the main pattern portion (MP; see FIG. 3) of the gate line GL.

A gate insulation layer GI may be disposed between the active layer ACT of the area in which the switching transistor SWTr is disposed and the gate electrode GE. Accordingly, the upper surface and both sides of the active layer ACT disposed under the transistor are covered by the gate insulation layer GI and the gate electrodes GE that are elongated from the gate line GL and not exposed to the outside.

A protective layer PAS is disposed on a substrate SUB comprising the gate electrode GE. The protective layer PAS may comprise an inorganic insulation material such as a silicon oxide SiOx and silicon nitride SiNx. The protective layer PAS may be thick enough to entirely cover the surfaces of the lower circuit elements such as the gate electrode GE, the gate line GL, the first and second connection wire lines CL1, CL2 and the like.

A planarization layer OC is disposed on the protective layer PAS. The planarization layer OC may be thick enough to planarize the upper surface which is stepped by circuit elements disposed on a substrate SUB below the planarization layer OC. The planarization layer OC may comprise an insulation material that is excellent in step coverage.

A first electrode PXL is disposed on the planarization layer OC. The first electrode PXL may comprise a transparent metallic oxide such as an indium tin oxide (ITO), or an indium zinc oxide (IZO), without being limited thereto. The first electrode PXL may also be referred to as an anode electrode or a pixel electrode.

A bank BNK comprising a bank hole BKH is disposed on the first electrode PXL. The bank hole BKH may define the surface area of the light-emitting area through the opening area OA that exposes a portion of the surface of the first electrode PXL. The bank BNK distinguishes each of the sub pixels. Additionally, the bank BNK reduces or prevents the mixture and output of different colors of light between adjacent sub pixels.

An organic emission layer EL and a second electrode CE are elongated along the surface of the first electrode PXL that is exposed by the bank hole BKH, and consecutively disposed on the bank BNK. The organic emission layer EL may be comprised of an organic material emitting white light, and its color may be expressed by a color filter, but not limited. The second electrode CE commonly contacts adjacent sub pixels on the display area AA to supply a voltage, without being limited thereto. As an example, the second electrode CE may be also individually disposed for each sub pixel. The second electrode CE may also be referred to as a cathode electrode or a common electrode, without being limited thereto.

An encapsulation part SEAL may be disposed on the second electrode CE. The encapsulation part SEAL may comprise a seal layer S1 and a cover part S2. The encapsulation part SEAL reduces or prevents moisture, air or particles and the like from coming into an organic light-emitting display apparatus. In an example, the seal layer S1 may be shaped into a multiple-layered structure that comprises at least one of an inorganic insulation layer comprising a silicon oxide (SiOx), a silicon nitride (SiNx), an aluminum oxide (AlOx), an aluminum nitride (AlNx) and the like, or an organic insulation layer, but not be limited.

The bank hole BKH may comprise a first opening area OA1 and a second opening area OA2. The second opening area OA2 may be shaped into a polygon that is elongated from the first opening area OA1 and comprises at least one or more of corner portions CP. The second opening area OA2 may protrude from the first opening area OA1 in the Y-axis direction that is the second direction, and have a width less than that of the first opening area OA1.

Referring to FIGS. 3, 5 and 6, the gate line GL may be disposed along the shape of at least one or more of corner portions CP of the second opening area OA that is a protruding portion of the bank hole BKH. The gate line GL may be disposed on the side of the corner portion CP of the second opening area OA of the bank hole BKH, and comprise a portion that bends along the shape of the corner portion CP. For example, the gate line GL may comprise a second bend portion BP2 that bends in a “L” shape in one side portion of the corner portion CP. Additionally, the gate line GL may be disposed to surround the corner portion of the second opening area OA2, without being limited thereto.

The gate line GL is formed along the shape of the corner portion CP of the bank hole BKH. Accordingly, a gate line GL comprising an opaque material is disposed in a portion adjacent to the corner portion CP of the bank hole BKH. As a result, light L1, which is emitted from the organic emission layer EL by driving the display apparatus, may be blocked or reflected in the direction of the bank BNK by a gate line GL adjacent to the opening area OA. Additionally, light L2 may be reduced or prevented from being input to the active layer ACT by the second bend portion BP2 of a gate line GL, which is disposed closer to the second opening area OA2 than the first bend portion BP1.

In other words, light may be reduced or prevented from being input to the active layer ACT of the switching transistor SWTr.

For example, in the case of a white sub pixel, since a color filter is not disposed at the white sub pixel, light is directly incident to the white sub pixel, and sensitivity to light is high. In the aspect, a structure in which the gate line GL is disposed to surround both sides of at least one corner portion of the second opening area OA2 is included. Accordingly, a sufficient separation distance from the bank hole BKH from which light is emitted may be secured. In accordance with, the input of light to the switching transistor SWTr or the sensing transistor STr is reduced or suppressed, reducing or preventing degradation of threshold voltage properties. Thus, the reliability of elements may be ensured, and the display apparatus may operate with low power, reducing power consumption.

Further, since the main pattern portion MP of the gate line GL comprises first and second bend portions BP1, BP2, the part where the sensing transistor STr is disposed and one side of the second opening area OA2 of the bank hole BKH may be spaced from each other by a first distance d1. At this time, the first distance d1 of the sensing transistor STr may be greater than a second distance d2 that is along the corner portion CP of the second opening area OA2 and formed between the second bend portion BP2 and the second opening area OA2.

Accordingly, the sensing transistor STr is sufficiently spaced from the bank hole BKH through which light emits, to reduce or suppress the input of light to the active layer of the sensing transistor STr.

As the distance between a portion where the sensing transistor STr and the switching transistor SWTr are disposed and the opening area OA where the bank hole BKH is disposed is closer, light may be introduced from the bank hole BKH into the portion where the sensing transistor STr and the switching transistor SWTr are disposed. In the case where light is input to the portion in which the sensing transistor STr and the switching transistor SWTr are disposed, the reliability of elements may deteriorate or be lowered.

In the aspect, the input of light to the active layer ACT of the switching transistor SWTr or the active layer ACT of the sensing transistor STr may be reduces, prevented or suppressed, reducing or preventing degradation in the negative bias thermal illumination stress (NBTIS) properties where a threshold voltage moves to a minus.

In the case where a gate line GL1 is disposed in a straight line shape unlike the gate line in the present disclosure, a distance between the portion where the sensing transistor STr and the switching transistor SWTr are disposed, and the opening area OA where the bank hole BKH is disposed may be less than the first distance d1 in the aspect.

However, in the case where a distance between the portion of where the sensing transistor STr or the switching transistor SWTr is disposed, and the opening area OA of the bank hole BKH decreases further, light may be input to the semiconductor layer of the sensing transistor STr or the switching transistor SWTr, at a time when the display apparatus operates, causing deterioration in the reliability of elements.

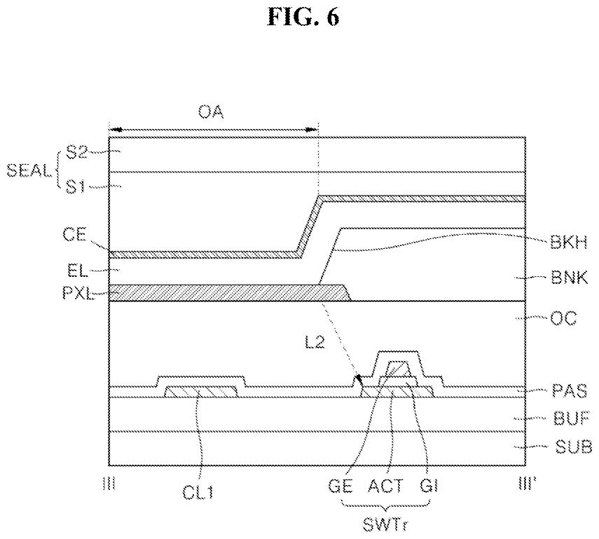

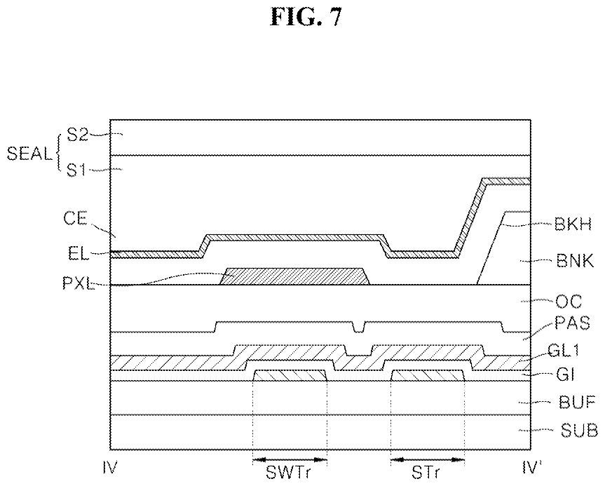

FIGS. 6 and 7 are cross-sectional views for explaining a problem or limitation caused by an input of light into an active layer.

Referring to FIGS. 6 and 7, an active layer ACT is disposed on the substrate SUB on which the buffer layer BUF is disposed. The active layer ACT may comprise at least one of an indium-gallium-zinc-oxide (IGZO)-based transparent semiconductor material, an indium-zinc-oxide (IZO)-based transparent semiconductor material, and the like, without being limited thereto.

A first or second connection wire line CL1, CL2 is formed with the same or similar material, on the same planar surface as the active layer ACT. A gate electrode GE may be disposed on the active layer ACT disposed in the area where the transistor is disposed. The gate electrode GE of each transistor may be a portion of the gate line GL1. For example, the gate electrode GE of the switching transistor SWTr may be defined as a portion of the gate line GL1. A gate insulation layer GI may be disposed between the active layer ACT of the area where the switching transistor SWTr or the sensing transistor STr is disposed, and the gate electrode GE, without being limited thereto.

In the case where a gate line GL1 in a straight line shape is disposed across the first or second connection wire line CL1, CL2 and defined as a gate electrode GE of the switching transistor SWTr or the sensing transistor STr, a portion of the upper surface of the active layer ACT may be exposed without being covered by the gate line GL1.

A protective layer PAS and a planarization layer OC are disposed on a substrate SUB comprising a gate electrode GE. The planarization layer OC may be thick enough to planarize the upper surface which is stepped by elements disposed on a substrate SUB below the planarization layer OC. A first electrode PXL is disposed on the planarization layer OC. The first electrode PXL may comprise a transparent metallic oxide such as an indium tin oxide (ITO), or an indium zinc oxide (IZO).

A bank BNK comprising a bank hole BKH is disposed on the first electrode PXL. The bank hole BKH may define the surface area of a light-emitting area through an opening area OA that exposes a portion of the surface of the first electrode PXL.

To increase the surface area of the opening area OA, first and second connection wire lines CL1, CL2 comprise transparent and conductive semiconductor material. Accordingly, the bank hole BKH may comprise a second opening area OA2 that is elongated from a first opening area OA1, to increase the light-emitting area.

Since the second opening area OA2 of the bank hole BKH expands in the direction toward the gate line GL1, the outermost portion of the opening area OA is disposed near the one side portion of the gate line GL1. Further, in the case where a gate line GL1 in a straight line shape is disposed across a first or second connection wire line CL1, CL2 and defined as the gate electrode GE of a switching transistor SWTr or a sensing transistor STr, a portion of the upper surface of the active layer ACT may be exposed without being covered by the gate line GL1, without being limited thereto.

For example, as illustrated in FIG. 6, a portion of the upper surface of the active layer ACT of the area where the switching transistor SWTr is disposed may be exposed. In the case where the display apparatus operates in the state where the upper surface of the active layer ACT is exposed, light L2 may be input to the exposed active layer ACT.

The active layer ACT comprises a semiconductor material that has a band gap of greater than 3 eV as an example, high transmittance in a visible light region, and transparent properties. At this time, the active layer ACT is more sensitive to light than a material having a band gap of less than 3 eV. Accordingly, in the case where light is input to the active layer ACT, negative bias thermal illumination stress properties may degrade where a threshold voltage moves to a minus.

The NBTIS properties may degrade further because an amount of light input to the active layer increases as a distance between the switching transistor SWTr or the sensing transistor STr and the opening area OA of the light-emitting area defined by the bank hole BKH decreases further.

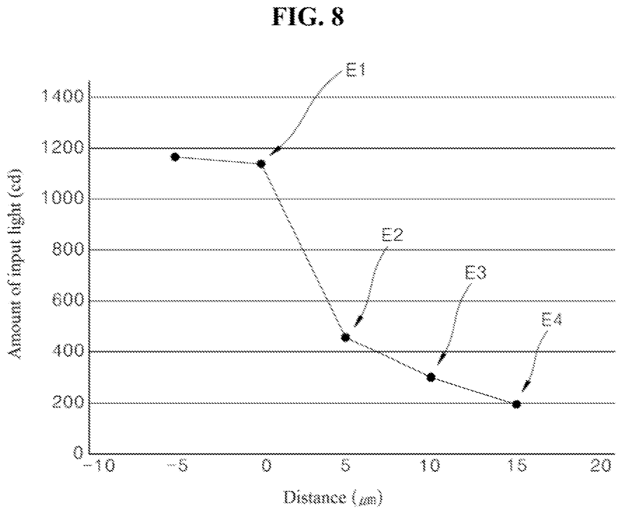

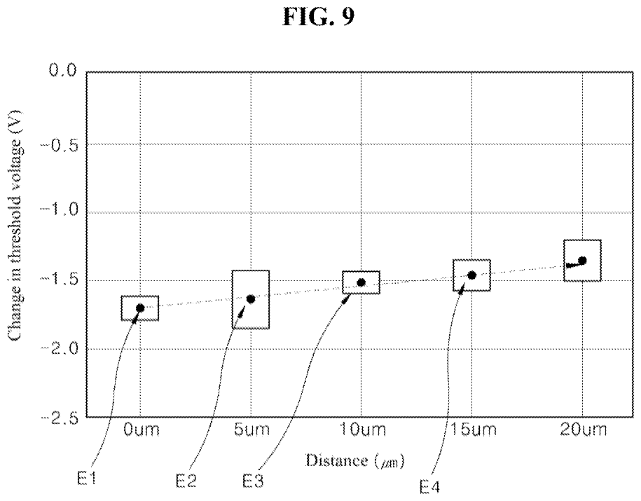

FIGS. 8 and 9 are graphs showing properties based on a distance between a transistor and an opening area of a light-emitting area. FIG. 8 is a graph showing amounts of input light, based on a distance between the switching transistor or the sensing transistor and the opening area of the light-emitting area. FIG. 9 is a graph showing a change in threshold voltages, based on a distance between the switching transistor or the sensing transistor and the opening area of the light-emitting area.

Referring to FIG. 8, in the case where a distance between the switching transistor SWTr or the sensing transistor STr and the opening area OA of the light-emitting area is close to 0 μm (E1), a largest amount of light is input to the active layer, and in the case where a distance between the switching transistor SWTr or the sensing transistor STr and the opening area OA of the light-emitting area increases further (E2, E3, E4), a decreasing amount of light is input to the active layer ACT. Referring to FIG. 9, in the case where a distance between the switching transistor SWTr or the sensing transistor STr and the opening area OA of the light-emitting area is close to 0 μm (E1), the degree to which a threshold voltage Vth changes in the minus (−) direction is the highest, and in the case where a distance between the switching transistor SWTr or the sensing transistor STr and the opening area OA of the light-emitting area increases further (E2, E3, E4), the degree to which a threshold voltage Vth changes in the minus (−) direction decreases.

In other words, as a distance between the switching transistor SWTr or the sensing transistor STr and the opening area OA of the light-emitting area decreases further, an amount of light input to the active layer ACT increases, and the NBTIS properties where a threshold voltage moves to a minus because of properties of the material of the active layer ACT sensitive to light may degrade further. Thus, a reduction in the amount of light input to the active layer ACT may lead to reduction or prevention of the degradation of NBTIS properties and improvement in the reliability of elements.

To this end, in one aspect, the gate line is disposed along the shape of at least one or more of corner portions of the expanded second opening area of the bank hole defining the light-emitting area. The gate line may comprise at least one or more of bend portions that are disposed on the side of the corner portions of both sides of the second opening area of the bank hole and bends along the shapes of the corner portions. As the gate line is formed along the shape of the corner portion of the bank hole, a gate electrode comprising an opaque metallic material may be disposed along the side of the bank hole through which light emits. Accordingly, even in the case where the display apparatus operates, and light emits from the organic emission layer, the emitted light may be blocked by the opaque metallic material of the gate line or the gate electrode or reflected in the direction of the bank. Since the input of light to the active layer is reduced, prevented or suppressed, degradation of the NBTIS properties where a threshold voltage moves to a minus may be prevented, ensuring the reliability of elements.

In one aspect, the input of light to the active layer is reduced or prevented based on the disposition of the gate line, the sensing transistor and the switching transistor, ensuring improvement in the stability and reliability of the elements.

In one aspect, since the connection wire line comprises a transparent and conductived semiconductor material, the opening area of the light-emitting area overlaps with the connection wire line, resulting in an increase in the surface area of the light-emitting area. Thus, the space of the sub pixels may be used efficiently, and the opening ratio may increase. Further, an increase in the surface area of the light-emitting area may lead to a decrease in the power consumption for embodying the same or similar luminance in each sub pixel.

Furthermore, the input of light to the active layer of the transistor is reduced or prevented, while the surface area of the light-emitting area increases, ensuring the reliability of the elements.

To this end, the gate line comprising at least one or more of bend portions is disposed along the shape of at least one or more of corner portions of the second opening area that is an elongated portion of the bank hole of the light-emitting area. Accordingly, the gate line comprising an opaque metallic material is disposed on the side of the corner portions of both sides of the second opening area of the bank hole, and a distance between the sensing transistor or the switching transistor and the opening area of the bank hole is ensured, reducing or preventing the input of light to the active layer and ensuring the reliability of the elements.

The display apparatus according to one or more exemplary embodiments of the present disclosure may be applied to mobile apparatuses, video phones, smart watches, watch phones, wearable apparatuses, foldable apparatuses, rollable apparatuses, bendable apparatuses, flexible apparatuses, curved apparatuses, variable apparatuses, sliding apparatuses, electronic organizers, electronic books, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theater apparatuses, theater display apparatuses, TVs, wall paper display apparatuses, signage apparatuses, game machines, notebook computers, monitors, cameras, camcorders, home appliances, etc.

Although the aspects of the present disclosure have been described in more detail with reference to the accompanying drawings, the present disclosure is not necessarily limited to these aspects, and may be modified in a various manner within the scope of the technical spirit of the present disclosure. Accordingly, the aspects as disclosed in the present disclosure are intended to describe rather than limit the technical idea of the present disclosure, and the scope of the technical idea of the present disclosure is not limited by these aspects. Therefore, it should be understood that the aspects described above are not restrictive but illustrative in all respects.

It will be apparent to those skilled in the art that various modifications and variations can be made in the display apparatus of the present disclosure without departing from the spirit or scope of the aspects of the present disclosure. Thus, it is intended that the present disclosure covers the modifications and variations of the aspects provided they come within the scope of the appended claims and their equivalents.

What is claimed is:

1. A display apparatus, comprising:
a plurality of sub pixels, a plurality of gate lines and a plurality of data lines being disposed on a substrate;
a bank disposed on the substrate, provided with a bank hole that comprises an opening area corresponding to a light-emitting area of each of the sub pixels, and distinguishing the light-emitting area of each of the sub pixels,
wherein the gate line is disposed along a shape of at least one of corner portions of the opening area and extends along a first direction.

2. The display apparatus of claim 1, wherein each of the plurality of plurality of sub pixels further comprises a driving transistor driving a sub pixel, a switching transistor or a sensing transistor, and at least one connection wire line, and
wherein the switching transistor or the sensing transistor comprises a portion of the connection wire line overlapping with the gate line as an active layer.

3. The display apparatus of claim 1, wherein the gate line comprises a main pattern portion extending in the first direction and comprising one or more bend portions, and
wherein the one or more bend portion of the main pattern portion is disposed along the corner portion of the opening area.

4. The display apparatus of claim 3, wherein the gate line is disposed in an “L” shape along one side portion that connects from the corner portion of the opening area of the bank hole.

5. The display apparatus of claim 3, wherein the bend portion of the gate line comprises a first bend portion being spaced from one side of the opening area of the bank hole in a second direction perpendicular to the first direction by a first distance; and a second bend portion being disposed along the corner portion of the second opening area and being spaced from the corner portion of the second opening area in at least one of the first direction and the second direction by a second distance, and
wherein the first distance is greater than the second distance.

6. The display apparatus of claim 2, wherein the at least one connection wire line of each sub pixel extends to overlap with a light-emitting area of an adjacent sub pixel.

7. The display apparatus of claim 2, wherein the at least one connection wire line of each sub pixel overlaps with the light-emitting area of the each sub pixel.

8. The display apparatus of claim 2, wherein the connection wire line comprises a semiconductor material having a band gap of greater than 3 eV, and transmitting a light in a specific wavelength range.

9. The display apparatus of claim 2, wherein the at least one connection wire line is configured to connect the driving transistor and the data line, or to connect the sensing transistor and a reference voltage supply line.

10. The display apparatus of claim 2, wherein the connection wire line comprises a semiconductor material, and a portion of the connection wire line not overlap the gate line is conductive.

11. The display apparatus of claim 2, wherein the gate line comprises a main pattern portion extending in the first direction and a projection pattern portion being branched from the main pattern portion and extending in a second direction perpendicular to the direction of the main pattern part, and
the switching transistor comprises a portion of the connection wire line overlapping the projection pattern portion as an active layer.

12. The display apparatus of claim 1, wherein the sub pixel comprises a white sub pixel, a blue sub pixel, a red sub pixel or a green sub pixel.

13. The display apparatus of claim 1, wherein the gate line surrounds one corner portion of the opening area.

14. The display apparatus of claim 1, wherein the gate line is disposed to surround both corner portions of the opening area adjacent to the gate line.

15. The display apparatus of claim 1, wherein the opening area comprises a first opening area and a second opening area which is elongated from the first opening area toward the gate line along a second direction perpendicular to the first direction and have a rectangle shape, and
the gate line is disposed along a shape of at least one of corner portions of the second opening area.

16. The display apparatus of claim 2, the width of the second opening area is less than the width of the first opening area.

17. A display apparatus, comprising:
a substrate comprising a plurality of sub pixels;
a gate line disposed on the substrate along a first direction;
a data line disposed along a second direction across the first direction; and
a bank comprising a bank hole that distinguishes a light-emitting area of each of the plurality of sub pixels and comprises at least one or more of corner portions,
wherein the gate line comprises a first bend portion being spaced from one side of the bank hole by a first distance in the second direction, and a second bend portion being disposed along the corner portion of the bank hole and being spaced from the corner portion of the bank hole by a second distance less than the first distance in at least one of the first direction and the second direction.

18. The display apparatus of claim 17, wherein the gate line further comprises a main pattern portion comprising the first bend portion and the second bend portion and extending in the first direction; and a projection pattern portion being branched from the main pattern portion and extending in the second direction.

19. The display apparatus of claim 17, wherein the display apparatus further comprises a plurality of connection wire lines that is disposed on the substrate and disposed to overlap with the light-emitting area of the sub pixel.

20. The display apparatus of claim 19, wherein each of the sub pixels further comprises driving transistor driving a sub pixel, a switching transistor or a sensing transistor, and
wherein the switching transistor or the sensing transistor comprises a portion of the gate line crossing the connection wire line as a gate electrode.

21. The display apparatus of claim 17, wherein the bank hole comprises a first opening area, and a second opening area extending from the first opening area toward the gate line.

22. The display apparatus of claim 21, wherein the gate line is disposed in an “L” shape along a side that connects from the corner portion of the second opening area of the bank hole.

23. The display apparatus of claim 19, wherein the connection wire line comprises a semiconductor material having a band gap of greater than 3 eV, and transmitting a light in a specific wavelength range.

24. The display apparatus of claim 19, wherein the connection wire line comprises a semiconductor material, and a portion of the connection wire line not overlap the gate line is conductive.

25. The display apparatus of claim 17, wherein the sub pixel comprises a white sub pixel, a blue sub pixel, a red sub pixel or a green sub pixel.

26. The display apparatus of claim 21, wherein the gate line surrounds one corner portion of the second opening area.

27. The display apparatus of claim 21, wherein the gate line is disposed to surround both corner portions of an opening area adjacent to the gate line.
